(19) United States
(12) Patent Application Publication
(10) Pub. No.: US 2011/0140074 A1
(43) Pub. Date: Jun. 16, 2011

(54) ROOM TEMPERATURE DISPENSER PHOTOCATHODE

(75) Inventors: Nathan A. Moody, Los Alamos, NM (US); David Charles Lizon, Rio Rancho, NM (US); Dinh Cong Nguyen, Los Alamos, NM (US)

(73) Assignee: LOS ALAMOS NATIONAL SECURITY, LLC, Los Alamos, NM (US)

(21) Appl. No.: 12/968,991

(22) Filed: Dec. 15, 2010

Related U.S. Application Data
(60) Provisional application No. 61/287,118, filed on Dec. 16, 2009.

(51) Int. Cl. H01L 31/0248; B82Y 99/00

(52) U.S. Cl. 257/10; 257/E31.002; 977/949

(57) ABSTRACT

Self-healing photocathode device comprising a photoemissive multi-alkali semiconductor comprising a multi-alkali antimonide having the formula AₓB_{y} C_{z}Sb, where A, B and C are Group I alkali metals and x+y+z=3; a nanostructured porous membrane, one surface of which is in direct contact with the multi-alkali semiconductor and the opposing surface of which is disposed toward the inside of a sealed reservoir, such that the porous membrane and the sealed reservoir form a volume which is maintained at low pressure; a temperature control means in contact with the porous membrane, wherein the temperature control means regulates the temperature of the porous membrane at 200° C. or less; a source comprising elemental cesium which is releasable into the enclosed volume; and, a current conducting means attached to the source.

### REFERENCE TO PRIOR APPLICATION

This application claims the benefit of priority of U.S. patent application Ser. 61/287,118, filed Dec. 16, 2009, and incorporated herein by reference in its entirety.

### STATEMENT OF FEDERAL RIGHTS

The United States government has rights in this invention pursuant to Contract No. DE-AC52-06NA25396 between the United States Department of Energy and Los Alamos National Security, LLC for the operation of Los Alamos National Laboratory.

### FIELD OF THE INVENTION

The present invention relates to a photocathode which operates at ambient temperatures, and comprises a means for controlled release of, e.g., elemental cesium to the cathode surface.

### BACKGROUND OF THE INVENTION

The concept of delivering an alkali coating to the surface of a cathode in order to lower work function and increase photosensitivity has been fundamental to the continued use and development of thermionic dispenser cathodes common to almost all vacuum electronic devices. In the notional “thermionic” dispenser cathode, an alkali-oxide compound impregnates an electrically and thermally conductive refractory matrix, which is then heated to >1000° C. The heating process chemically reduces the alkali oxide, freeing alkali atoms to diffuse to the emitting surface (due to concentration gradient) where they lower the work function and enable thermionic emission. These cathodes are extremely rugged and exhibit very long lifetimes on the order of tens to hundreds of kilo-hours.

A fundamental problem with thermionic emitters, however, is their characteristically low current density and inability to be gated for short pulse emission. These limitations preclude their use in the cutting edge applications which dominate vacuum electronics industries (such as high power, high frequency RF and optical radiation sources) and motivate the use of photo-emitting electron sources. With photo-emitting electron sources, the electron emission does not require high temperature but rather is a result of photoexcitation and subsequent emission of electrons in the cathode. Photocathodes exhibit the requisite high peak and high average current densities, along with the ability to precisely gate emission in time, but also have the disadvantage of relatively short life-times.

An important metric for evaluating photoemission cathodes is quantum efficiency (QE), which is defined to be the ratio of emitted electrons to incident photons. In practice, it is observed that higher QE is accompanied by a shorter lifetime. This is because the photoemissive surfaces are comprised of thin film, alkali-based semiconductors which are vulnerable to contamination and desorption. In an operational environment of an RF accelerator, a typical alkali-based photocathode having QE of 2-10% lasts only several hours. Such a short lifetime severely limits their practical use in applications such as free electron lasers and x-ray sources which require gated, high-current electron beams at high duty cycle.

Studies have been conducted to evaluate the performance of commercial thermionic cathodes as photoemitters. Specifically, the temperature was lowered below that required for thermionic emission (but high enough to release small amounts barium, a photosensitive material) and an incident laser pulse was used to induce photoemission. While this study was an important step and led to significant theory development, the measured QE was severely low (<0.01% at 532 nm) and the temperature required to deliver alkali atoms to the surface was far too high (approximately 1000-2000° C.) to be used with multi-alkali high QE coatings, given that such materials break down at approximately 200° C.

In a photoemission scheme, a light source (typically a laser or high intensity LED) impinges a photocathode in vacuum and liberates charge due to the photoelectric effect: an incident photon imparts energy to an electron in the photocathode and if the electron migrates to the cathode surface with energy higher than the work function (the energy barrier to cross into vacuum) then it is emitted as part of the beam. For a drive laser to have practical output power and wavelength, a high QE is needed to maximize electron beam current.

QE is most often improved by coating various metallic or semiconductor surfaces with thin layer(s) of alkali-metals that dramatically reduce work function. These coatings are the basis for the ultra-high sensitivities achieved in photo multiplier tubes (PMTs) which serve as sensitive light detectors. In the rather harsh vacuum environment of an electron gun, however, these coatings do not survive for long periods of time: several hours are typical for many popular high QE compounds. The highest QE materials contain cesium, either as a compound, a surface coating, or a combination thereof. A persistent and unresolved problem in photocathode development is that the highest QE coatings exhibit the shortest lifetimes in an electron gun (at visible wavelengths). Thus, the full potential of these materials is limited because most photocathode applications, such as medical x-ray sources and even high power light sources such as the free electron laser, cannot benefit from operational lifetimes of only several hours.

A need exists, therefore, for long-lived photocathodes with high quantum efficiency (QE) at the longest possible wavelength. A further need exists for a cathode which has the long-life characteristic of metal emitters as well as the high QE of multi-alkali coatings.

### SUMMARY OF THE INVENTION

The present invention meets the aforementioned need by employing a barrier comprising a diffusive material for the cathode substrate, which is in connection with a reservoir of a purified elemental alkali metal, one suitable example of which is cesium. A photoactive, or photoemissive, layer of material is in contact with the barrier. The high concentration gradient of the alkali across the diffusive material, together with gentle heating, allows the alkali to diffuse through the barrier at a controlled rate. This reservoir is designed such that the quantity of alkali, the rate of alkali delivery, and the temperature of the porous substrate can be independently controlled. One aspect of the present invention is that the cathode substrate temperature is controllable and kept well below 200° C., since at this temperature the multi-alkali coating on the surface begins to dissociate and is irrevocably damaged. However, during assembly of the cathode, the temperature may be elevated to a higher temperature; as the multi-layered hetero-structure of the present invention requires different temperatures during the multi-layer fabrication process (i.e., top-layers of alkali films react with sub-layers at different temperatures). The present invention meets all these requirements and allows alkali diffusion to occur after fabrication at a low temperature, avoiding the problem of dissociation during rejuvenation. Gentle heating of the substrate, together with independent adjustment of alkali concentration within the reservoir, allows for fine tuning of the diffusion rate. This, in turn, allows the alkali to be replenished at a rate required to maintain the photosensitive cathode films. This approach increases the effective lifetime of a basic cesium coating on sintered tungsten metal by roughly two orders of magnitude.

The following describes some non-limiting embodiments of the present invention.

According to one embodiment of the present invention, a self-healing photocathode device is provided, comprising a photoemissive multi-alkali semiconductor comprising a multi-alkali antimonide having the formula AₓB_{y}C_{z}Sb, where A, B and C are Group I alkali metals and x+y+z=3; a nanostructured porous membrane, one surface of which is in direct contact with the multi-alkali semiconductor and the opposing surface of which is disposed toward the inside of a sealed reservoir, such that the porous membrane and the sealed reservoir form a volume which is maintained at low pressure; a temperature control means in contact with the porous membrane, wherein the temperature control means regulates the temperature of the porous membrane at 200° C. or less; a source comprising elemental cesium which is releasable into the enclosed volume; and, a current conducting means attached to the source.

According to another embodiment of the present invention, a photocathode device is provided, comprising a photoemissive multi-alkali semiconductor comprising a multi-alkali antimonide having the formula AₓB_{y}C_{z}Sb, where A, B and C are Group I alkali metals and x+y+z=3; a nanostructured porous membrane, one surface of which is in direct contact with the multi-alkali semiconductor substrate and the opposing surface of which is disposed toward the inside of a sealed reservoir, such that the porous membrane and the sealed reservoir form a volume which is maintained at low pressure; a temperature control means in contact with the porous membrane, wherein the temperature control means regulates the temperature of the porous membrane at 200° C. or less; a source comprising elemental cesium which is releasable into the enclosed volume; and, a current conducting means attached to the source; wherein the photocathode is self-healing and has a 1/e lifetime of at least 500 hours.

According to yet another embodiment of the present invention, a self-healing photocathode device is provided, comprising a photoemissive multi-alkali semiconductor comprising a multi-alkali antimonide having the formula K₂CsSb; a nanostructured porous membrane comprising tungsten, one surface of which is in direct contact with the multi-alkali semiconductor substrate and the opposing surface of which is disposed toward the inside of a sealed reservoir, such that the porous membrane and the sealed reservoir form a volume which is maintained at low pressure; a temperature control means in contact with the porous membrane, wherein the temperature control means regulates the temperature of the porous membrane at 200° C. or less; a source comprising elemental cesium which is releasable within the enclosed volume; and, a current conducting means attached to the source; wherein the self-healing photocathode device has a 1/e lifetime of from about 500 hours to about 10,000 hours.

### BRIEF DESCRIPTION OF THE DRAWINGS

FIG. 1 depicts schematically one embodiment of the self-healing low temperature dispenser photocathode of the present invention, wherein the reservoir of elemental alkali metal is situated within the evacuated chamber.

FIG. 2 depicts an alternative embodiment of the present invention, wherein the reservoir of elemental alkali metal is situated outside the evacuated chamber.

FIG. 3 shows data supporting the enhanced 1/e lifetime of the present invention.

### DETAILED DESCRIPTION OF THE INVENTION

The present invention describes self-healing photocathodes. Herein, “self-healing” is understood to mean that elemental alkali metals which are lost during the photoemission process are replenished, e.g. from a reservoir, at substantially the same rate at which they are lost and without excessive heating. This self-healing aspect distinguishes the present invention from other types of cathodes, such as thermionic cathodes, which require high operating temperatures, and traditional photocathodes which do not have a means for replenishing lost elemental compounds and thus suffer the drawback of short lifetimes.

Photocathodes are specialized electron sources that find application in medical x-ray machines, RF linacs, free electron lasers, and particle accelerators. In x-ray imaging, the photocathodes of the present invention could replace traditional electron beam sources (thermionic cathodes) resulting in a dramatic reduction in system size, complexity, and cost. In accelerator applications, light pulses, incident on the photocathode are used to photo-switch the electron beam to create short bunches containing high charge that are then fed into an RF accelerating structure. This technique is called photoinjection and it is superior to other methods of beam, generation (i.e., thermionic emission) in terms of electron beam brightness and quality. It has been shown that alkali-based photocathodes degrade because the alkali leaves the emitting surface (both through desorption and chemical reaction with trace gases in the electron gun).

The present invention describes a low temperature dispenser photocathode, which in one embodiment comprises a hermetically sealed cylindrical volume, capped at one end by a nanostructured porous membrane which comprises the cathode substrate. In one non-limiting embodiment, purified, elemental cesium is placed inside the volume, e.g. in a container such as an ampoule, and a concentration gradient is established across the porous membrane, which, together with gentle heating, allows cesium to diffuse to the surface at a controllable rate. As cesium arrives at the surface, it restores and maintains the low workfunction coating responsible for high QE.

In an alternative embodiment, a eutectic alloy, packaged in a resistive envelope, may be used in place of an ampoule to release the purified cesium. The eutectic alloy comprises cesium, but does not evolve or emit cesium until reaching a certain temperature. The envelope containing this alloy is thermally isolated from the interior of the dispenser cathode. When the eutectic alloy is resistively heated (by passing an electrical current through its envelope) above 400° C., elemental cesium is released into the dispenser without significantly heating the dispenser itself. By allowing this process to continue over time, the total amount of cesium released within the dispenser can be selected and known by using the relationship between rate of cesium evolution and the current through the envelope.

Successful reconditioning of even the most basic alkali cathodes must occur at relatively low temperatures, in order to prevent damage to the coating the process is intending to improve. Rather than using an impregnated matrix of alkali oxides heated to high temperature, the present invention utilizes a porous cathode substrate (one non-limiting example of which is sintered tungsten) in contact with a controllable reservoir of cesium. These features, together with its low-temperature performance, differentiate this cathode from existing technologies. Specifically, the cathode of the present invention typically operates at or near room temperature, and has a maximum operating temperature of about 200° C. or lower.

The present invention embodies several novel aspects. First, a purified alkali metal can be introduced into the cathode and transferred to the vacuum system, where it is outgassed and baked, before the alkali is released. Once released, the alkali diffuses to the surface at or near room temperature without destroying the multi-alkali compound. The alkali-containing cartridge is electrically activated and controlled, allowing one to fine tune the total amount of alkali in the reservoir as well as the rate at which it is released. Additionally, the entire device can be repeatedly re-used by simply re-inserting a new electrically activated alkali-containing cartridge (or any combination of alkali metals) when the original is depleted. The photocathode of the present invention efficiently produces an electron beam at a low temperature for a long operational period.

The present invention exhibits several benefits. First, the present invention may be amenable to use with multi-alkali coatings, which are well understood and researched. Second, the surface replenishment of cesium using our approach occurs at a low temperature. Many of the high QE multi-alkali coatings (CsK₂Sb, CsKNaSb, etc.) become chemically unstable at temperatures approaching 200° C. The present invention completely avoids the risk of overheating the cathode surface by allowing low temperature operation. Third, the present invention may serve as a platform on which any number of alkali-based cathodes can be built, and may be used to extend the lifetime of an entire range of cathode coatings by adjusting temperature and the alkali specie(s) contained within. Additionally, the cathode assembly, comprising sintered tungsten brazed to a stainless steel sleeve which is welded to a miniature vacuum flange, can be easily refilled with alkali when needed. By simply separating the cathode assembly from the ampoule housing, a new ampoule can be inserted with minimal effort. This reduces operational and maintenance costs because the same cathode can be re-used multiple times. Many manufacturers desire “table-top” accelerators for high power sources of THz, IR, visible, UV, and x-ray light. A long-lived, commercially available high QE photocathode could allow further development of technology in these applications. Finally, in the field of vacuum electronics, photocathodes (together with a low power laser diode or LED) could be used to replace the power-hungry thermionic emitters which have been the mainstay in many applications such as x-ray tubes used for medicine and national security. Despite recent advances in commercial x-ray sources, all still use thermionic emitters to create an electron beam. In each case, the supply used to power the cathode filament heater has to be held at tens to hundreds of kilovolts potential. This leads to an unavoidably large form factor, in addition to the large power load, which is a limiting factor in further miniaturization of these sources. Replacing a hot thermionic emitter with a low temperature emitter having similarly long life could potentially lead to a drastic reduction in the size and cost of x-ray sources.

“Multi-alkali semi-conductor,” as used herein, denotes a family of semi-conducting materials comprising a multi-alkali antimonide having the formula AₓB_{y}C_{z}Sb, where A, B and C are Group I alkali metals and x+y+z=3.

“Nanostructured porous membrane,” as used herein, means a material comprising internal structures such as grains and pores, wherein the material has nanoscale grains, pores and grain boundaries. Herein, “grain” is understood to mean the smallest single-crystal volume of a polycrystalline material that locally shares the same crystallographic orientation, usually on a microscopic scale. “Pore” is understood to mean a microscopic void in a material whose orientation can be either random or preferential with respect to its macroscopic dimensions “Grain boundaries” are understood to mean the interface between crystallite grains within a polycrystalline material. The nanostructured porous membranes of the present invention may have a porosity of about 30%, which is understood to mean that on average the voids (or pores) in the material occupy 30% of the overall volume.

“1/e lifetime,” as used herein, means the time after the start of operation of the photocathode, at which the quantum efficiency is reduced by about 36.8% of its observed maximum value.

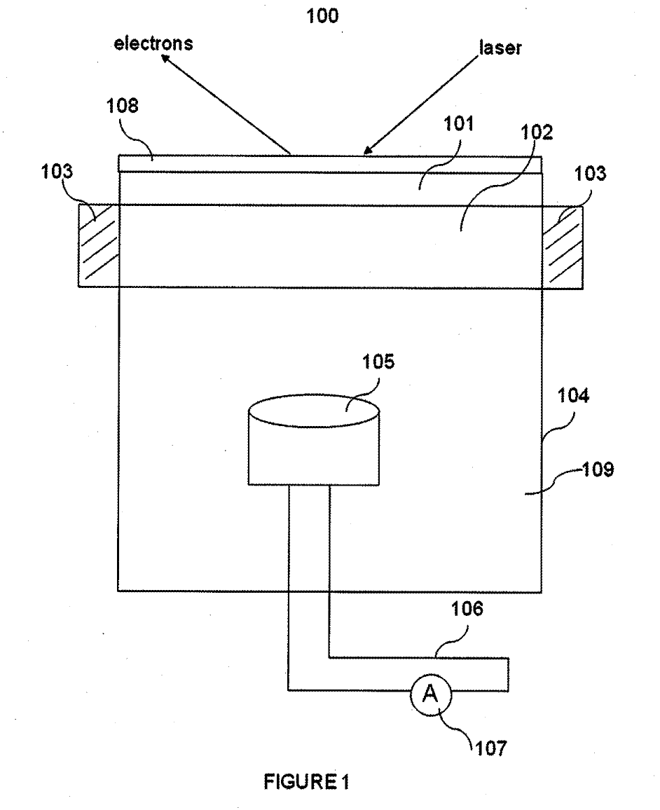

“Low pressure,” as used herein, means a nominal pressure of about 1×10⁻⁹ torr or lower. FIG. 1 depicts one embodiment of a self-healing photocathode 100 of the present invention. Laser energy is directed onto photoemissive multi-alkali semiconductor 101. Photoemissive multi-alkali semiconductor 101 may have a thickness of from about 100 nm to about 1000 nm, and alternatively is about 500 nm. Optionally, photoemissive multi-alkali semiconductor 101 may comprise a photoemission enhancing monolayer 108, comprising elemental cesium and/or rubidium. In one embodiment, the photoemission enhancing monolayer 108 comprises elemental Cs. The optional photoemission enhancing monolayer 108 has been shown to provide additional enhancement of photosensitivity, and may actually be less than a monolayer thick. Photoemissive multi-alkali semiconductor 101 further may incorporate additional sublayers (not depicted). The photoemissive multi-alkali semiconductor 101 comprises a multi-alkali antimonide having the formula AₓB_{y} C_{z}Sb, where A, B and C are Group I alkali metals and x+y+z=3. In one embodiment, A, B and C are selected from the group consisting of Na, K, Cs, Rb, and combinations thereof. In one embodiment, the multi-alkali antimonide is K₂CsSb. The monolayer comprises a Group I alkali metal, which in one embodiment is Cs. Methods of making photoemissive materials suitable for use in the present invention are described in Varma et al., J. Phys. D: Appl. Phys., v. 6, pp. 628-632 (1973).

Photoemissive multi-alkali semiconductor 101 is in direct contact with nanostructured porous membrane 102, which in turn is surrounded by a thermally conductive collar 103 or other temperature control means, which serves to regulate the temperature of the porous membrane 102. Regulation of temperature in turn allows control of the rate of replenishing of the alkali metal, as this controls the rate of diffusion through the porous membrane. It is critical that the temperature be maintained below the temperature at which the multi-alkali antimonides begin to exhibit degradation, which typically is 200° C. or lower, and alternatively is from about 25° C. to about 200° C. In one embodiment the temperature is maintained at about 25° C. In addition, the temperature control means must allow for regulation of the temperature during fabrication in a range of from about 50° C. to about 250° C. Nanostructured porous membrane 102 is fitted atop container 104, such that nanostructured porous membrane 102 and container 104 form a sealed volume 109, intended for operation at nominal pressure of 5×10⁻⁹ torr or lower. Nanostructured porous membrane 102 may comprise any material exhibiting atomic diffusive properties due to its nanoscale porosity, together with a mechanically rigid form such that it provides support for the photosensitive layers grown upon it. In one embodiment, nanostructured porous membrane 102 comprises a material selected from the group consisting of sintered tungsten, porous silicon carbide, and combinations thereof. Alternatively, nanostructured porous membrane 102 may comprise other electrically conducting materials exhibiting characteristics similar to sintered tungsten or porous silicon carbide. The nanostructured porous membrane 102 may have a thickness of from about 0.01 mm to about 1 mm, and may have a diameter of about 1 cm to about 10 cm. The nanostructured porous membrane 102 further comprises pores and grain boundaries having an average diameter of from about 1 nm to about 1000 nm, and grains having a size of from about 10 nm to about 1000 nm. The porosity of the nanostructured porous membrane may be about 30%.

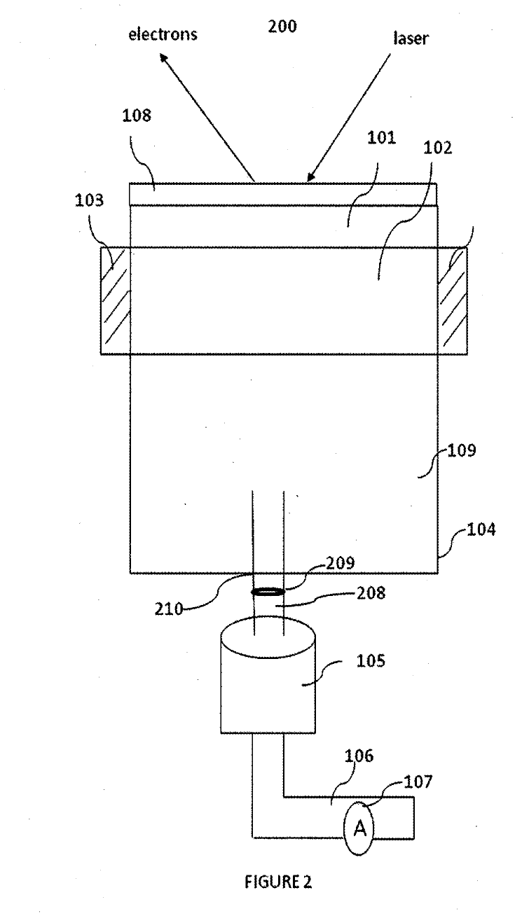

In contact with container 104 is a source 105 comprising a Group I alkali metal compound, which in one embodiment is purified cesium, wherein “purified” is understood to mean at least 99% purity. Source 105 may comprise any source capable of functioning as a reservoir and releasing the Group I alkali metal compound into the sealed volume 109. In one embodiment, source 105 is an ampoule. Alternatively, source 105 may be a eutectic alloy, or other suitable alkali metal-containing compounds. The Group I alkali metal compound is releasable into the sealed volume 109. This may occur directly, in the case where the source 105 is wholly contained within the sealed volume. Alternatively, source 105 may be situated outside sealed volume 109, as depicted in FIG. 2. In this embodiment, the Group I alkali metal compound is releasable into sealed volume 109 via a tube 208 or other means of connection. The tube 208 enters sealed volume 109 via a vacuum seal 210, and comprises a valve 209 or other means for regulating the flow of the Group I alkali metal into the sealed volume 109. in all embodiments, conducting means 106, such as electrical contact wires, are attached to source 105, and serve to conduct electrical current to the source, which in turn provides a means of temperature regulation. Power source 107 serves to regulate the electrical current.

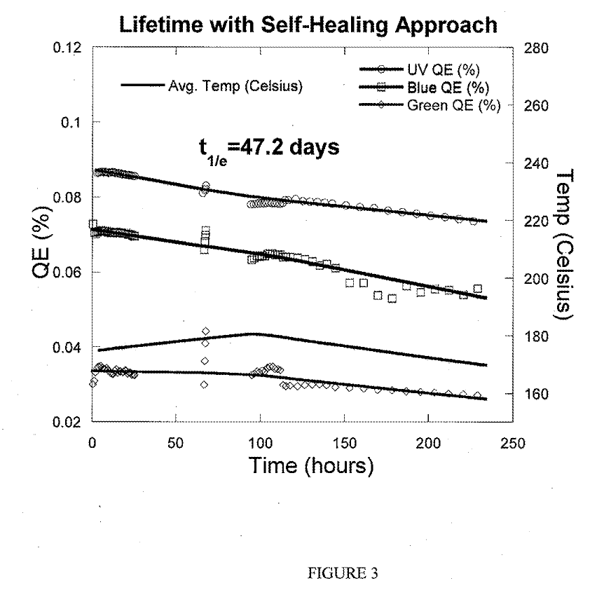

FIG. 3 depicts data showing the extended lifetime of the self-healing photocathode of the present invention. The various lines depict the quantum efficiency (QE) as a function of time at wavelengths corresponding to the blue, green and ultraviolet regions of the electromagnetic spectrum. Though not shown in the plot, it was determined that the extrapolated lie lifetime of the self-healing photocathode was 47.2 days.

In all embodiments of the present invention, all percentages are by weight of the total composition, unless specifically stated otherwise. All ranges are inclusive and combinable. All numerical amounts are understood to be modified by the word “about” unless otherwise specifically indicated. All documents cited in the Detailed Description of the Invention are, in relevant part, incorporated herein by reference; the citation of any document is not to be construed as an admission that it is prior art with respect to the present invention. To the extent that any meaning or definition of a term in this document conflicts with any meaning or definition of the same term in a document incorporated by reference, the meaning or definition assigned to that term in this document shall govern.

Whereas particular embodiments of the present invention have been illustrated and described, it would be obvious to those skilled in the art that various other changes and modifications can be made without departing from the spirit and scope of the invention. It is therefore intended to cover in the appended claims all such changes and modifications that are within the scope of this invention.

What is claimed is:

1. A self-healing photocathode device comprising:
a) a photoemissive multi-alkali semiconductor comprising a multi-alkali antimonide having the formula AₓB_{y}C_{z}Sb, where A, B and C are Group I alkali metals and x+y+z=3;
b) a nanostructured porous membrane, one surface of which is in direct contact with the multi-alkali semiconductor and the opposing surface of which is disposed toward the inside of a sealed reservoir, such that the porous membrane and the sealed reservoir form a volume which is maintained at low pressure;
c) a temperature control means in contact with the porous membrane, wherein the temperature control means regulates the temperature of the porous membrane at 200° C. or less;
d) a source comprising elemental cesium which is releasable into the enclosed volume; and,
e) a current conducting means attached to the source.

2. The self-healing photocathode device of claim 1, wherein A, B and C each independently are selected from the group consisting of Cs, K, Na, Rb and combinations thereof.

3. The self-healing photocathode device of claim 1, wherein the multi-alkali antimonide is K₂CsSb.

4. The self-healing photocathode device of claim 1, wherein the nanostructured porous membrane comprises sintered tungsten, porous silicon carbide, or combinations thereof.

5. The self-healing photocathode device of claim 1, wherein the nanostructured porous membrane comprises grains having a size of from about 10 nm to about 1000 nm.

6. The self-healing photocathode device of claim 1, wherein the nanostructured porous membrane comprises pores and grain boundaries having a size of from about 1 nm to about 1000 nm.

7. The self-healing photocathode device of claim 1, wherein the nanostructured porous membrane has a thickness of from about 0.1 mm to about 1 mm.

8. The self-healing photocathode device of claim 1, wherein the photoemissive multi-alkali semiconductor has a thickness of from about 100 nm to about 1000 nm.

9. The self-healing photocathode device of claim 1, wherein the pressure is 5×10⁻⁹ torr or less.

10. The self-healing photocathode device of claim 1, wherein the photoemissive multi-alkali semiconductor further comprises a photoemission enhancing monolayer thereupon.

11. The self-healing photocathode device of claim 1, wherein the photocathode has a 1/e lifetime of at least 500 hours.

12. The self-healing photocathode device of claim I, wherein the cesium source is contained within the enclosed volume.

13. A photocathode device comprising:
a) a photoemissive multi-alkali semiconductor comprising a multi-alkali antimonide having the formula AₓB_{y}C_{z}Sb, where A, B and C are Group I alkali metals and x+y+z=3;
b) a nanostructured porous membrane, one surface of which is in direct contact with the multi-alkali semiconductor substrate and the opposing surface of which is disposed toward the inside of a sealed reservoir, such that the porous membrane and the sealed reservoir form a volume which is maintained at low pressure;
c) a temperature control means in contact with the porous membrane, wherein the temperature control means regulates the temperature of the porous membrane at 200° C. or less;
d) a source comprising elemental cesium which is releasable into the enclosed volume; and,
e) a current conducting means attached to the source;
wherein the photocathode is self-healing and has a 1/e lifetime of at least 500 hours.

14. The self-healing photocathode device of claim 13, wherein A, B and C each independently are selected from the group consisting of Cs, K, Na, Rb and combinations thereof.

15. The self-healing photocathode device of claim 13, wherein the nanostructured porous membrane comprises sintered tungsten, porous silicon carbide, or combinations thereof.

16. The self-healing photocathode device of claim 13, wherein the nanostructured porous membrane comprises grains having a size of from about 10 nm to about 1000 nm.

17. The self-healing photocathode device of claim 13, wherein the nanostructured porous membrane comprises pores and grain boundaries having a size of from about 1 nm to about 1000 nm.

18. The self-healing photocathode device of claim 13, wherein the nanostructured porous membrane has a thickness of from about 0.1 mm to about 1 mm.

19. The self-healing photocathode device of claim 13, wherein the photoemissive multi-alkali semiconductor has a thickness of from about 100 nm to about 1000 nm.

20. The self-healing photocathode device of claim 13, wherein the pressure is 5×10⁻⁹ torr or less.

21. The self-healing photocathode device of claim 13, wherein the cesium source is contained within the enclosed volume.

22. The self-healing photocathode device of claim 13, wherein the photoemissive multi-alkali semiconductor further comprises a photoemission enhancing monolayer thereupon.

23. A self-healing photocathode device comprising:
a) a photoemissive multi-alkali semiconductor comprising a multi-alkali antimonide having the formula K₂CsSb;
b) a nanostructured porous membrane comprising tungsten, one surface of which is in direct contact with the multi-alkali semiconductor substrate and the opposing surface of which is disposed toward the inside of a sealed reservoir, such that the porous membrane and the sealed reservoir form a volume which is maintained at low pressure;
c) a temperature control means in contact with the porous membrane, wherein the temperature control means regulates the temperature of the porous membrane at 200° C. or less;
d) a source comprising elemental cesium which is releasable within the enclosed volume; and,
e) a current conducting means attached to the source;
wherein the self-healing photocathode device has a 1/e lifetime of from about 500 hours to about 10,000 hours.

24. The self-healing photocathode device of claim 23, wherein the nanostructured porous membrane comprises grains having a size of from about 10 nm to about 1000 nm.

25. The self-healing photocathode device of claim 23, wherein the nanostructured porous membrane comprises pores and grain boundaries having a size of from about 1 nm to about 1000 nm.

26. The self-healing photocathode device of claim 23, wherein the nanostructured porous membrane has a thickness of from about 0.1 mm to about 1 mm.

27. The self-healing photocathode device of claim 23, wherein the photoemissive multi-alkali semiconductor has a thickness of from about 100 nm to about 1000 nm.

28. The self-healing photocathode device of claim 23, wherein the pressure is 5×10⁻⁹ torr or less.

29. The self-healing photocathode device of claim 23, wherein the cesium source is contained within the enclosed volume.

30. The self-healing photocathode device of claim 23, wherein the temperature control means regulates the temperature of the porous membrane at 25° C. or less.

31. The self-healing photocathode device of claim 23, wherein the photoemissive multi-alkali semiconductor further comprises a photoemission enhancing monolayer thereupon.
